(19) United States
(12) Patent Application Publication
(10) Pub. No.: US 2026/0313863 A1
(43) Pub. Date: Oct. 8, 2026

(54) OPERATION MANAGEMENT APPARATUS AND OPERATION MANAGEMENT METHOD FOR FEEDER

(71) Applicant: FUJI CORPORATION, Chiryu (JP)

(72) Inventor: Akira HARA, Toyohashi-shi (JP)

(73) Assignee: FUJI CORPORATION, Chiryu (JP)

(21) Appl. No.: 19/482,335

(22) PCT Filed: Jun. 19, 2023
(86) PCT No.: PCT/JP2023/022578

§ 371 Date: Nov. 7, 2025

(51) Int. Cl. H05K 13/08

(52) U.S. Cl. CPC H05K 13/086; H05K 13/0882

(57) ABSTRACT

An operation management apparatus includes: an acquisition section configured to acquire a type of a device in which a feeder configured to supply a component is set; and a mode setting section configured to set an operation mode of the feeder including a normal mode in which a supply operation of the component is executable and a power saving mode in which power consumption is reduced as compared with the normal mode based on the acquired type of the device.

### TECHNICAL FIELD

The present disclosure relates to an operation management apparatus and an operation management method for a feeder.

### BACKGROUND ART

An operation management apparatus for a feeder manages an operation of a feeder that is set in a component mounter and used to supply components. As shown in Patent Literature 1, the component mounter constitutes a production system for producing board products together with other board work machines, a management device, a warehouse, and an off-line setup device. When the feeder is prepared in a usable state by off-line set up, for example, the feeder is conveyed from the off-line setup device to a specific component mounter via a predetermined standby place and used.

### CITATION LIST

### Patent Literature

Patent Literature 1: WO 2020/115915

### BRIEF SUMMARY

### Technical Problem

In order to obtain a current position of each feeder, the management device of the production system is capable of communicating with the feeders in a case where the feeders are set in, for example, a component mounter or a buffer device serving as a standby place. However, when the state in which the power supply is turned on is maintained such that the feeder can communicate, power is consumed regardless of a standby state, and there is a concern that the influence on a production cost increases as the number of feeders held increases.

An object of the present description is to provide an operation management apparatus and an operation management method for a feeder capable of suppressing power consumed by the feeder in a production system, thereby reducing a production cost.

### Solution to Problem

The present description discloses an operation management apparatus for a feeder, the apparatus including: an acquisition section configured to acquire a type of a device in which a feeder configured to supply a component is set; and a mode setting section configured to set an operation mode of the feeder including a normal mode in which a supply operation of the component is executable and a power saving mode in which power consumption is reduced as compared with the normal mode based on the acquired type of the device.

The present description discloses an operation management method for a feeder, the method including: an acquisition step of acquiring a type of a device in which a feeder configured to supply a component is set; and a mode setting step of setting an operation mode of the feeder including a normal mode in which a supply operation of the component is executable and a power saving mode in which power consumption is reduced as compared with the normal mode based on the acquired type of the device.

### Advantageous Effects

According to this configuration, since the operation mode of the feeder is switched according to the type of the device in which the feeder is set, it is possible to suppress the power consumed by the feeder in the production system. As a result, a production cost can be reduced.

### BRIEF DESCRIPTION OF DRAWINGS

FIG. 1 is a diagram illustrating a production system including an operation management apparatus.

FIG. 2 is a perspective view illustrating a production line.

FIG. 3 is a perspective view schematically illustrating a configuration of a loader and a component mounter of FIG. 1.

FIG. 4 is a perspective view illustrating an appearance of a feeder in FIG. 3.

FIG. 5 is a block diagram illustrating the production system to which the operation management apparatus is applied.

FIG. 6 is a table illustrating the state and the like of each section corresponding to an operation mode.

FIG. 7 is a flowchart illustrating an operation control process.

FIG. 8A is a block diagram illustrating a first modification corresponding to FIG. 5.

FIG. 8B is a block diagram illustrating a second modification corresponding to FIG. 5.

### DESCRIPTION OF EMBODIMENTS

### 1. Production System 10

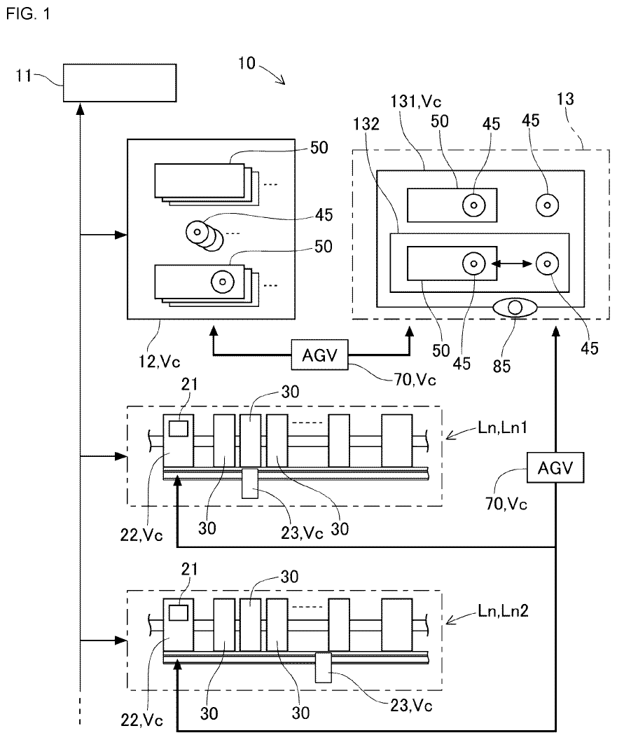

Hereinafter, an embodiment of an operation management apparatus will be described with reference to the drawings. The operation management apparatus is set in a component mounter constituting a production line in the embodiment, and manages an operation of a feeder used for supplying a component. In the present embodiment, as illustrated in FIG. 1, production system 10 includes multiple production lines Ln, host computer 11, management warehouse 12, and work area 13.

### 1-1. Production Line Ln

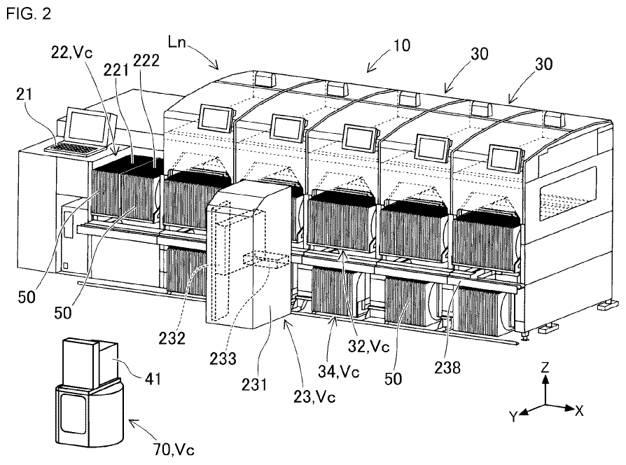

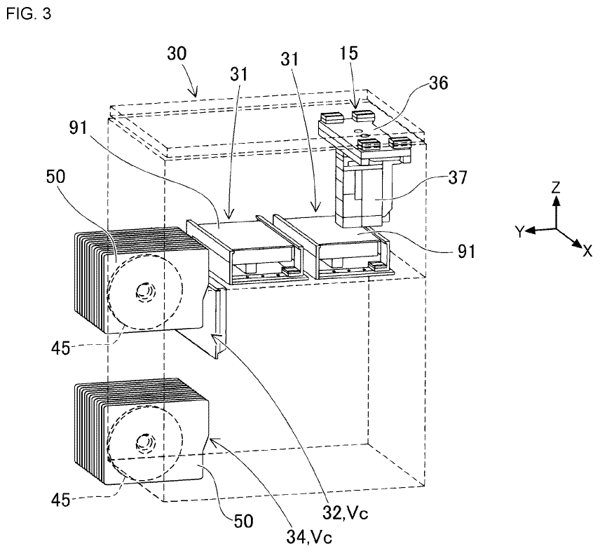

In the present embodiment, production system 10 includes multiple production lines Ln including first production line Ln1 and second production line Ln2. As illustrated in FIGS. 1 and 2, production line Ln is configured to have multiple component mounters 30 installed side by side in a conveyance direction of board 91 (refer to FIG. 3). Production line Ln includes line management device 21, line buffer device 22, and loader 23.

Line management device 21 is configured to communicate with multiple production devices (such as component mounter 30) constituting production line Ln, line buffer device 22, loader 23, and self-propelled work robot 70 via a network. Line management device 21 monitors an operation status of production line Ln, and integrally controls multiple component mounters 30 and the like. Line management device 21 records a control program used in the mounting processes by component mounter 30, the progress of each mounting process, and the like.

Line buffer device 22 is used for storing cassette-type feeder 50. Line buffer device 22 temporarily holds feeder 50 loaded with the component to be used in the mounting process as the production of the product board and feeder 50 used in the mounting process. When feeder 50 is held by multiple slots (not illustrated), line buffer device 22 supplies power to feeder 50 and becomes communicable. Accordingly, line buffer device 22 can read an identification code (ID) unique to feeder 50 held in the slot. Line buffer device 22 is installed, for example, on the board carry-in side (left side in FIG. 1) of production line Ln.

Loader 23 conveys feeder 50 between each of multiple component mounters 30 and line buffer device 22. Specifically, loader 23 is provided to travel along a travel path formed by a rail extending over the entire area in the conveyance direction of board 91 on the front side of multiple component mounters 30. Configurations of component mounter 30 and loader 23 will be described later.

In addition, the configuration of production line Ln can be appropriately added or changed according to, for example, the type of product board to be produced. Specifically, a board work machine such as a solder printer, an inspection machine, and a reflow oven can be appropriately installed in production line Ln. First production line Ln1 and second production line Ln2 may be different in configuration, feeder 50 to be set, and the like according to the type of product board to be produced. Production system 10 may be provided with three or more production lines.

### 1-2. Host Computer 11

Host computer 11 is a management device that monitors the operation status of each device constituting production system 10 and work robot 70, and integrally controls them. Host computer 11 stores various data for controlling production line Ln and the like. As illustrated in FIG. 1, host computer 11 is configured to communicate with line management device 21 of production line Ln, management warehouse 12, automatic loading device 132 installed in work area 13, and the like via a network.

### 1-3. Management Warehouse 12

Management warehouse 12 delivers the component based on a delivery command from the outside. Management warehouse 12 is configured to store reel 45 around which carrier tape 46 accommodating multiple components is wound and feeder 50 loaded with carrier tape 46. Management warehouse 12 may store feeder 50 loaded with carrier tape 46.

Management warehouse 12 includes a conveyance device that conveys feeders 50 and the like between a predetermined storage position in a storage shelf that holds feeders 50 and the like and a work table on which feeders 50 and the like are temporarily placed during storage and delivery. When the component is delivered, the conveyance device grips a reel or the like located at the predetermined storage position and, for example, reads an identification code (ID) attached to the reel or the like to check whether the component is correct. Thereafter, the conveyance device places the held reel or the like on the work table.

### 1-4. Work Area 13

Work area 13 in which setup work for production is performed is provided between multiple production lines Ln and management warehouse 12. The setup work in work area 13 described above includes work of loading a component into feeder 50. Work area 13 is provided with work table 131 for transferring feeder 50 and reel 45, and automatic loading device 132. Automatic loading device 132 is a device that automatically loads reel 45 into set feeder 50.

The loading work of loading carrier tape 46 into feeder 50 may be performed using automatic loading device 132 or may be performed manually by worker 85. In work area 13, worker 85 performs various types of work. The above-described various types of work include, for example, work of removing carrier tape 46 loaded in feeder 50 used in the mounting process. The association information between feeder 50 and reel 45 is updated as carrier tape 46 is loaded into feeder 50, and the association information is discarded as reel 45 is removed.

### 2. Component Mounter 30

As illustrated in FIG. 3, multiple component mounters 30 constituting production line Ln include board conveyance device 31, component supply device 32, main buffer device 34, and head driving device 35. In the following description, it is assumed that a horizontal width direction of component mounter 30, which is the conveyance direction of board 91, is an X direction, a horizontal depth direction of component mounter 30 is a Y direction, and a vertical direction (up-down direction of FIG. 3) perpendicular to the X direction and the Y direction is a Z direction.

Board conveyance device 31 includes a belt conveyor, a positioning device, and the like. Board conveyance device 31 subsequently conveys board 91 in the conveyance direction and positions board 91 at a predetermined position in the machine. Board conveyance device 31 carries board 91 out of component mounter 30 after the mounting process performed by component mounter 30 is terminated.

Component supply device 32 supplies components to be mounted on board 91. Component supply device 32 has a slot in which feeder 50 can be set. Component supply device 32 is disposed in an upper part on a front part side of component mounter 30 and holds set feeder 50 in an operational manner. That is, an operation of feeder 50 set in the slot of component supply device 32 is controlled in the mounting process by component mounter 30 to supply the component in a take-out section provided at a defined position of an upper part of feeder 50.

Main buffer device 34 is provided in component mounter 30 and is configured to accommodate spare feeder 50. Specifically, main buffer device 34 is disposed below the slot of component supply device 32 and stocks set feeders 50. That is, main buffer device 34 preliminarily holds feeder 50 to be used for production, or temporarily holds used feeder 50 used for production. The exchange of feeder 50 between component supply device 32 and main buffer device 34 is performed by automatic exchange by loader 23 or by manual exchange by a worker.

In addition, in a case where feeder 50 is set in a slot of component supply device 32 or a slot of main buffer device 34, power is supplied from component mounter 30 via a connector. Feeder 50 is in a state in which it can communicate with component mounter 30. Feeder 50 set in component supply device 32 controls a feeding operation of carrier tape 46 accommodating the component based on a control command or the like by component mounter 30. As a result, feeder 50 supplies the component in the take-out section provided in the upper part of feeder 50, so that the component can be picked up by a holding member of mounting head 37 described later.

Head driving device 35 transfers the component supplied by component supply device 32 to a predetermined mounting position on board 91 carried into the machine by board conveyance device 31. Head driving device 35 moves moving table 36 in a horizontal direction (X direction and Y direction) by a linear motion mechanism. Mounting head 37 is fixed to moving table 36 in an exchangeable manner by a clamp member (not illustrated). Mounting head 37 picks up the component and mounts the component on board 91 by adjusting an up-down direction position and an angle of the component.

Specifically, the holding member that holds the component supplied by feeder 50 is attached to mounting head 37. As the holding member, for example, a suction nozzle that holds a component with supplied negative pressure air or a chuck that grips and holds the component can be applied. Mounting head 37 holds the holding member to be movable in the Z direction and to be rotatable around a θ axis parallel to a Z axis. Mounting head 37 is moved in the XY directions by the linear motion mechanism of head driving device 35.

Component mounter 30 having the configuration as described above executes the mounting process that mounts the component on board 91. In the mounting process, component mounter 30 transmits a control signal to head driving device 35 based on a result of the image processing, a result detection by various sensors, a control program stored in advance, or the like. As a result, the positions and the angles of multiple suction nozzles supported by mounting head 37 are controlled.

The suction nozzle held by mounting head 37 is appropriately changed according to the type of the component mounted on board 91 in the mounting process. In a case where the suction nozzle used in the mounting process to be executed is not held by mounting head 37, component mounter 30 causes mounting head 37 to hold the suction nozzle accommodated in a nozzle station (not illustrated). The nozzle station is detachably set in a predetermined position in component mounter 30.

### 3. Line Buffer Device 22

As illustrated in FIG. 2, in the present embodiment, line buffer device 22 includes first storage section 221 and second storage section 222. Magazine 41 for feeder 50 is detachably equipped in first storage section 221 and second storage section 222. Magazine 41 is formed with multiple slots and is configured to hold feeder 50 in each slot. In this manner, line buffer device 22 holds feeder 50 by equipped magazine 41.

First storage section 221 and second storage section 222 are provided side by side in order from the upstream side in the conveyance direction of board 91. In the present embodiment, each of first storage section 221 and second storage section 222 is configured to be equipped with one magazine 41. Feeder 50 set in magazine 41 equipped in line buffer device 22 is supplied with power and is in a state in which it can communicate with line management device 21 via a control device of line buffer device 22. As a result, the slot of line buffer device 22 and an identification code (ID) of feeder 50 set in the slot are associated with each other and recorded in line management device 21.

### 4. Configuration of Loader 23

Loader 23 is provided to be movable along the conveyance direction of board 91 with respect to multiple production devices (in the present embodiment, component mounter 30 and line buffer device 22). Loader 23 executes predetermined work on a predetermined production device. In the present embodiment, as the above-described predetermined work, loader 23 executes exchange operation of exchanging feeder 50 between multiple component mounters 30 and line buffer device 22.

In a case where work area 13 is installed adjacent to production line Ln, loader 23 can execute the above-described exchange operation between multiple component mounters 30, line buffer device 22, work table 131, and automatic loading device 132. In addition, loader 23 may be used to exchange an exchange element, which is detachably set on the board work machine such as component mounter 30, with the board work machine.

As illustrated in FIG. 2, loader 23 moves along a travel path including rails 238 provided at a front part of multiple component mounters 30 and line buffer device 22. Rail 238 extends over substantially the entire area in the conveyance direction of board 91 in production line Ln. Loader 23 is supplied with power via rail 238 in a non-contact manner from an opposing production device according to the position of loader 23 itself.

Loader 23 includes main body 231. Main body 231 is provided to be travelable along the travel path formed by rail 238. Specifically, main body 231 includes a traveling roller and a guide roller that are rollingly engaged with rail 238. As a result, main body 231 is maintained in its posture, is movable in the X direction, and is regulated from moving in the Y direction and the Z direction. In addition, main body 231 may be provided with a feeder holding section capable of holding multiple feeders 50. The feeder holding section holds multiple feeders 50 in a state of being aligned in the X direction. Loader 23 is configured to supply power to feeder 50, for example, in the feeder holding section, and can function as device Vc in which feeder 50 is set.

Loader 23 includes feeder exchange device 232. Feeder exchange device 232 exchanges feeder 50 with a device in which feeder 50 is set. In the present embodiment, feeder exchange device 232 exchanges feeder 50 with multiple component mounters 30 constituting production line Ln and with line buffer device 22. Exchange of feeder 50 includes recovering and replenishment of feeder 50. In the present embodiment, feeder exchange device 232 exchanges feeder 50 with various devices including component supply device 32 and main buffer device 34 of component mounter 30, and line buffer device 22.

Feeder exchange device 232 is configured to move held feeder 50 with respect to main body 231 in an attachment/detachment direction (Y direction in the present embodiment) and the up-down direction (Z direction) of feeder 50. With such a configuration, feeder exchange device 232 lifts and lowers held feeder 50 to a height corresponding to the slot of the device. In the present embodiment, feeder exchange device 232 is used to replace feeder 50 between component supply device 32 and main buffer device 34 of component mounter 30 and to convey used feeder 50 from component mounter 30 to line buffer device 22.

Loader 23 includes loader moving device 233. Loader moving device 233 is driven by power supplied from the outside to cause main body 231 to travel. In a case where a battery is mounted on main body 231, loader moving device 233 may be driven by power supplied from the battery. In addition, loader moving device 233 is combined with rail 238, for example, to constitute a linear motor. At this time, loader moving device 233 generates a propulsive force in the X direction with respect to rail 238 by supplying power to a moving coil (not illustrated), and moves loader 23 in the X direction.

Loader 23 includes a loader control device (not illustrated). The loader control device is a controller mainly including CPU, various memories, and a control circuit. The loader control device is communicatively connected to multiple component mounters 30, line buffer device 22, and line management device 21. The loader control device controls the operations of loader moving device 233, feeder exchange device, and the like.

The loader control device detects a current position of main body 231 on the travel path based on a detection signal by a position detection sensor (not illustrated). Specifically, the above-described position detection sensor is disposed to face a linear scale provided on rail 238, for example, and detects a scale of the linear scale. In addition, an optical detection method or a detection method using electromagnetic induction can be applied to the position detection sensor for detecting the position of main body 231. In this way, loader 23 is configured to move along rail 238 to a predetermined position and to exchange feeder 50 at the stopped position.

### 5. Configuration of Feeder 50

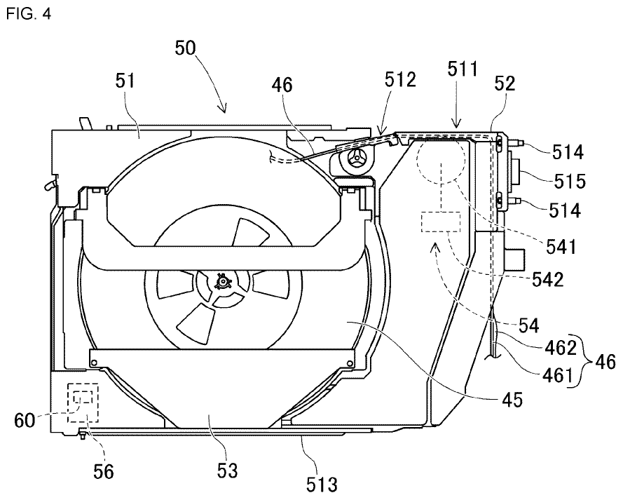

A configuration of feeder 50 will be described with reference to FIG. 4. The left-right direction in FIG. 4 is the conveyance direction of carrier tape 46, the left side in FIG. 4 is the upstream side in the conveyance direction, and the right side in FIG. 4 is the downstream side in the conveyance direction. In the present embodiment, feeder 50 is a tape feeder that executes a supply operation to supply components by feeding and moving carrier tape 46. Feeder 50 includes feeder main body 51. Feeder main body 51 is formed in a flat box shape. In feeder main body 51, component supply position 511 for supplying a component is formed in an upper part on the downstream side in the conveyance direction of carrier tape 46.

In feeder main body 51, tape conveyance path 512 that guides carrier tape 46 pulled out from reel 45 to component supply position 511 is formed. Tape conveyance path 512 is formed in a rectangular tubular shape using, for example, a bottom plate, two side plates, and a ceiling plate. Tape conveyance path 512 may include a tape presser that presses carrier tape 46 against the bottom plate side. A part of the cylindrical shape of tape conveyance path 512 may be omitted. Tape conveyance path 512 extends obliquely upward in the downstream direction with a position close to reel 45 as a start point, extends substantially horizontally in the downstream direction from the middle, and has an upper part of the downstream end of feeder main body 51 as an end point. A position close to the end point of tape conveyance path 512 is component supply position 511.

Detachable rail 513 is provided on the lower surface of feeder main body 51. Detachable rail 513 holds the posture of feeder 50 by being fitted into a slot provided in various devices such as component supply device 32 and magazine 41, and supports the movement of feeder 50. Positioning pin 514 and connector 515 are provided on an end surface of feeder main body 51. Positioning pin 514 is inserted into a positioning hole of a device in which feeder 50 is set, and positions feeder 50 with respect to the device. In a case where the receiving side connector is provided in the device, connector 515 is fitted to the receiving side connector and connected to enable power supply and communication to feeder 50.

Feeder 50 includes tape guide 52. Tape guide 52 is detachably provided on the upper part of feeder main body 51. Tape guide 52 peels off one end of cover tape 462 in the width direction from base tape 461 constituting carrier tape 46, thereby opening cavities for individually accommodating components. Base tape 461 with the cavities opened is conveyed to component supply position 511 and supplies the components. Thereafter, base tape 461 is discharged below feeder 50 together with cover tape 462 that has passed above tape guide 52.

Feeder 50 includes reel holding section 53. Reel holding section 53 holds reel 45 on which carrier tape 46 is wound in an exchangeable manner. Reel holding section 53 rotatably holds the outer peripheral edge of reel 45 or the center of reel 45. Reel holding section 53 is provided with an openable and closable holding cover to prevent reel 45 from deviating.

Feeder 50 includes drive device 54 that feeds and moves a tape accommodating multiple components in a component supply operation. Drive device 54 includes sprocket 541 rotatably supported by feeder main body 51. The teeth of sprocket 541 protrude from a groove formed in the bottom plate of tape conveyance path 512 and engage with feed holes formed at predetermined intervals in carrier tape 46. Drive device 54 includes electric motor 542 that generates a driving force transmitted to sprocket 541 via a speed reducer (not illustrated). Electric motor 542 is capable of intermittent operation and continuous operation, and is capable of switching between forward rotation and reverse rotation. Drive device 54 rotates sprocket 541 with electric motor 542 to feed and move carrier tape 46.

Drive device 54 can convey carrier tape 46 at a constant pitch in the conveyance direction and supply the components in order at component supply position 511. In addition, drive device 54 can continuously convey newly set carrier tape 46 in the conveyance direction. Further, drive device 54 can continuously convey partially used carrier tape 46 in the reverse direction to perform part of the removal work.

Feeder 50 includes feeder control device 56. Feeder control device 56 controls the operation of drive device 54. When feeder 50 is set in component supply device 32 of component mounter 30, power is supplied from component mounter 30 via connector 515. As a result, feeder control device 56 is in a state in which it can communicate with component mounter 30. With such a configuration, it is detected that feeder 50 is set in component supply device 32 or main buffer device 34 of component mounter 30.

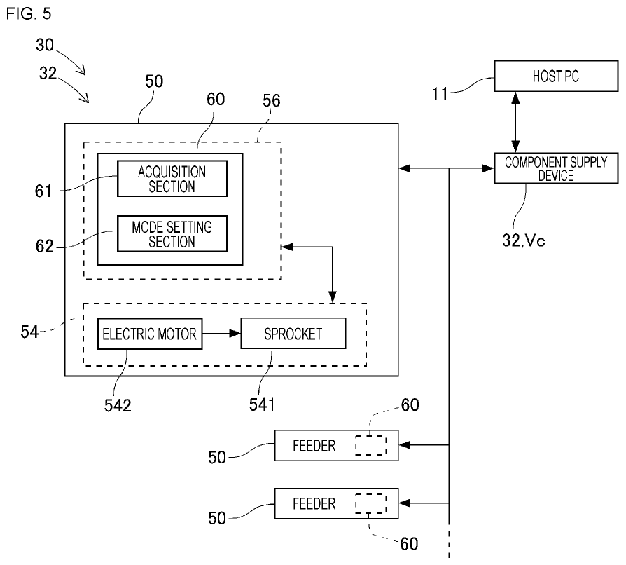

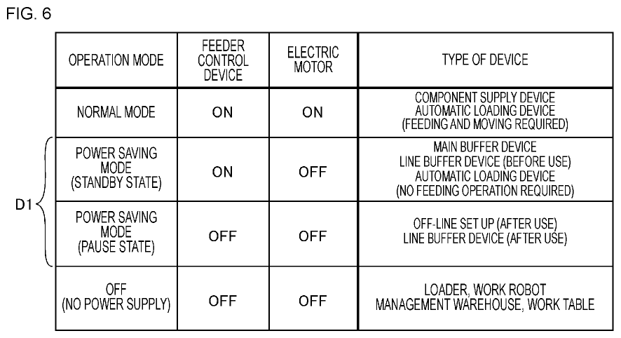

Various types of control information are stored in advance in feeder control device 56. The control information includes an identification code (ID) of feeder 50, a program and a correction value used when controlling drive device 54, and device information D1 (refer to FIGS. 5 and 6) regarding a device in which feeder 50 can be set. Details of the operation management using device information D1 will be described later.

### 6. Operation Management Apparatus 60 of Feeder 50

In a case where feeder 50 is used for production of a product board in production system 10 as described above, feeder 50 is delivered from management warehouse 12 and loaded with carrier tape 46 in work area 13. After the off-line set up is performed as described above, feeder 50 is carried into line buffer device 22 of predetermined production line Ln by work robot 70 or worker 85, and is moved to component supply device 32 or main buffer device 34 of component mounter 30 by loader 23 at a predetermined timing.

In this way, feeder 50 passes through management warehouse 12 and component mounter 30 in a state in which it is set in various devices Vc. When feeder 50 is put to trial use in a production process by component mounter 30, feeder 50 is conveyed from component mounter 30 to management warehouse 12 and stored therein in a process in a substantially reverse order to that described above. In order to obtain the current position of each feeder 50, host computer 11, which serves as a management device of production system 10 is capable of communicating with feeders 50 in a case where feeders 50 are set in, for example, component mounter 30 or line buffer device 22 serving as a standby place.

However, when feeder 50 is kept powered on such that it can communicate, power is consumed even when it is in a standby state. As the number of feeders 50 applied to production in production system 10 increases, the influence on the production cost is concerned. Therefore, in the present embodiment, operation management apparatus 60 and an operation management method for feeder 50 are employed, which can suppress power consumed by feeder 50 in production system 10, thereby reducing a production cost. In the present embodiment, as illustrated in FIG. 5, an aspect in which operation management apparatus 60 is incorporated in feeder control device 56 is exemplified.

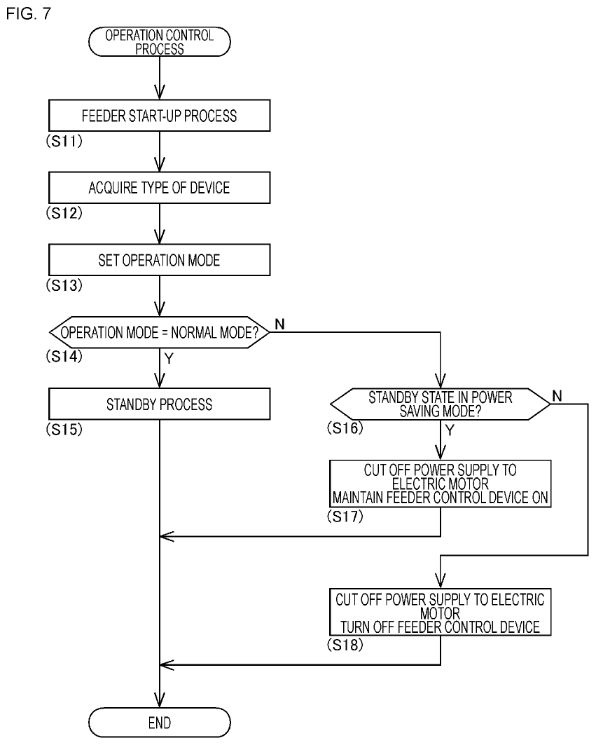

As illustrated in FIG. 5, operation management apparatus 60 includes acquisition section 61 and mode setting section 62. Operation management apparatus 60 executes the operation management method of feeder 50 in an operation management process illustrated in FIG. 7. Acquisition section 61 executes an acquisition step (S12). Mode setting section 62 executes a mode setting step (S13).

### 6-1. Acquisition Section 61

Acquisition section 61 acquires the type of device Vc in which feeder 50 that supplies the component is set. In the present embodiment, since acquisition section 61 is incorporated in feeder control device 56, acquisition section 61 acquires the type of device Ve specified by feeder control device 56. Specifically, when feeder 50 is set in any one of devices Vc, feeder control device 56 executes a start-up process (S11).

The start-up process includes starting communication with device Vc, reading a control program, checking the operation of various sensors, and the like, and may also return sprocket 541 of drive device 54 to its original position as necessary. In the start-up process, feeder control device 56 acquires the type of specified device Vc by communicating with device Vc. Specifically, as illustrated in FIG. 5, when feeder 50 is set in component supply device 32 as device Vc, feeder control device 56 transmits its own identification code (ID) to component supply device 32 and inputs the type of device Vc from component supply device 32.

Then, acquisition section 61 acquires the current type of device Vc (S12). Further, in the present embodiment, also in a case where feeder 50 is set in main buffer device 34 or line buffer device 22, when power is supplied to feeder 50 by the set, communication between feeder control device 56 and device Vc is started, and acquisition section 61 acquires the type of device Vc.

For example, in a case where feeder 50 is set in management warehouse 12, work table 131, or work robot 70 (including an indirect set via magazine 41), if power is not supplied from these devices Vc to feeder 50, there is no room for power saving in feeder 50, and the process of acquiring the type of these devices Vc is omitted. However, in work robot 70, a conveyance cart (not illustrated) of feeder 50, or the like, in a case where there is a situation such as requiring a feeding operation of carrier tape 46 by feeder 50, power can be supplied to feeder 50. At this time, acquisition section 61 acquires the type of device Vc in which feeder 50 is set.

### 6-2. Mode Setting Section 62

Mode setting section 62 sets the operation mode of feeder 50 based on the acquired type of device Vc (S13). As illustrated in FIG. 6, the above-mentioned “operation mode” includes a normal mode in which a component supply operation can be executed and a power saving mode in which power consumption is reduced as compared with the normal mode. Here, the “normal mode” is an operation mode in which feeder 50 stands by to execute a component supply operation in response to an operation command from a control device on device Vc side, for example, a control device of component mounter 30, and power is supplied to feeder control device 56 and electric motor 542. In the normal mode, electric motor 542 is ready to operate immediately and consumes standby power.

The above-mentioned “power saving mode” is an operation mode in which power consumption is reduced by stopping at least some of functions of feeder 50. In the present embodiment, in the power saving mode, power supply to feeder control device 56 is maintained, and power supply to electric drive device 54 used in the component supply operation except for feeder control device 56 is stopped. More specifically, in the power saving mode, the power supply to electric motor 542 constituting drive device 54 is cut off to stop the function of the feeding and moving. This eliminates the consumption of standby power in electric motor 542.

As illustrated in FIG. 6, the power saving mode may include a standby state in which power supply to feeder control device 56 is maintained as described above and a pause state in which power supply to feeder control device 56 is cut off. In the power saving mode in the pause state, power supply to feeder control device 56 is stopped, and power supply to electric drive device 54 used in the component supply operation except for feeder control device 56 is stopped.

In the pause state, for example, an energization lamp (not illustrated) of feeder 50 is turned on. The pause state may be cancelled by a predetermined operation such as a button operation for accepting a shift to the standby state, removal from device Vc, or re-supply of power. The power saving mode may be a standby state in which power is always supplied to feeder control device 56 during a period in which feeder 50 is set in device Vc and power is supplied.

Mode setting section 62 sets the operation mode based on the type of device Ve acquired by acquisition section 61. In the present embodiment, mode setting section 62 sets the operation mode based on device information D1 stored in feeder control device 56 and the type of device Vc. Here, as illustrated in FIG. 6, “device information D1” is information indicating the type of device Vc that can be set to the power saving mode. In the present embodiment, device information D1 indicates that the power saving mode can be set in a case where the type of device Vc in which feeder 50 is set is line buffer device 22 or main buffer device 34.

Device information D1 is appropriately adjusted according to the production environment of production system 10 or the like, and even when the type of device Vc is the same, it may be classified whether the power saving mode can be set according to whether feeder 50 is before or after being used for production. Accordingly, device information D1 is adjusted depending on a case where priority is given to power saving in production system 10 as a whole, a case where priority is given to productivity maintenance, or the like.

In the mode setting step (S13), mode setting section 62 sets the operation mode of feeder 50 to the power saving mode when the type of device Ve acquired in the acquisition step (S12) is included in device information D1. In a case where the type of device Ve acquired by acquisition section 61 is component supply device 32, mode setting section 62 sets the operation mode of feeder 50 to the normal mode.

As illustrated in FIG. 6, for example, in a case where feeder 50 is set in automatic loading device 132 as device Vc and the feeding and moving of carrier tape 46 is necessary in the loading operation, mode setting section 62 may set the operation mode to the normal mode. On the other hand, in automatic loading device 132 and work table 131, the feeding and moving of carrier tape 46 is performed by an operation force from the outside, and in a case where the operation of electric motor 542 is unnecessary, mode setting section 62 may set the operation mode to the power saving mode.

### 6-3. Operation of Feeder 50

When the operation mode is set by the mode setting step (S13) and the operation mode is the normal mode (S14: Yes), feeder control device 56 executes a standby process (S15). Accordingly, feeder 50 maintains the power supply to feeder control device 56 and drive device 54, can communicate with the outside, and can respond to an operation command (for example, a component supply command) from the outside.

When the operation mode is not the normal mode (S14: No) and is set to the standby state in the power saving mode (S16: Yes), feeder control device 56 cuts off the power supply to drive device 54 while maintaining the power-on of feeder control device 56 (S17). Accordingly, feeder 50 maintains the power supply to feeder control device 56 and can communicate with the outside, and electric motor 542 does not consume standby power.

When feeder control device 56 is not in the standby state in the power saving mode (S16: No), feeder control device 56 assumes that it has been set to the pause state in the power saving mode, cuts off the power supply to drive device 54, and executes its own termination process to turn off the power (S18). As a result, feeder 50 enters a state in which communication with the outside is cut off and electric motor 542 does not consume standby power, for example, only by turning on the energization lamp. In an aspect in which the pause state is not included in the power saving mode, the state determination regarding the power saving mode (S16) may be omitted, and the process of cutting off the power supply to drive device 54 (S17) may be executed.

### 7. Effects of Configuration of Embodiment

According to the configuration of exemplary operation management apparatus 60 and operation management method, since the operation mode of feeder 50 is switched according to the type of device Vc in which feeder 50 is set, it is possible to suppress the power consumed by feeder 50 in production system 10. As a result, a production cost can be reduced.

In addition, according to the configuration in which acquisition section 61 and mode setting section 62 are provided in feeder control device 56 as in the present embodiment, when a large number of feeders 50 used for production in production system 10 are set in device Vc, each feeder 50 can individually set its own operation mode. Accordingly, it is possible to set the operation mode of feeder 50 without performing communication with a higher-level management device (host computer 11 or line management device 21) related to the operation management process.

### 8. Modification of Embodiment

### 8-1. Operation Management According to Type of Feeder 50

In the present embodiment, operation management apparatus 60 suppresses unnecessary power consumption by stopping the power supply to drive device 54 in feeder 50 according to the type of device Vc. Here, feeder 50 feeds and moves carrier tape 46 by drive device 54, and peels off one end of cover tape 462 in the width direction using a peeling mechanism provided in tape guide 52. Then, base tape 461 and cover tape 462 that have passed through component supply position 511 are discharged below feeder 50.

There are types of feeders 50 that differ from the above configuration. For example, unlike the semi-peeling type exemplified in the embodiment in which only one end of cover tape 462 in the width direction is peeled off, there is a full peeling type in which cover tape 462 is peeled off from base tape 461 over the entire area in the width direction at tape guide 52. In this full peeling type feeder 50, peeled cover tape 462 passes above tape conveyance path 512 toward the upstream side, and is either recovered by a recovery device provided inside feeder 50 or discharged to outside feeder 50.

Such feeder 50 includes an electric recovery motor that applies tension to cover tape 462 to feed and move cover tape 462 to a recovery device or outside feeder 50. In addition, in a case where a recovery device employs an aspect in which cover tape 462 is wound around a predetermined recovery reel, the recovery motor is used to drive the recovery reel to rotate. The recovery motor is caused to operate in synchronization with electric motor 542 of drive device 54.

As described above, when feeder 50 includes an electric motor different from electric motor 542 of drive device 54 (for example, a full peeling type recovery motor), operation management apparatus 60 may set these electric motors as targets of operation management. That is, for example, when the operation mode of feeder 50 is set to the power saving mode, operation management apparatus 60 performs control such that power supply to electric motor 542 of drive device 54 that feeds and moves carrier tape 46 and the recovery motor that feeds and moves peeled cover tape 462 is cut off. According to such an aspect, the consumption of standby power can be further reduced.

### 8-2. Arrangement of Operation Management Apparatus 60

In the embodiment, acquisition section 61 and mode setting section 62 of operation management apparatus 60 are configured to be provided in feeder control device 56. As a result, when each feeder 50 is set in device Vc and supplied with power, its own operation mode can be set. On the other hand, acquisition section 61 and mode setting section 62 may be configured to be provided in an external device of feeder 50.

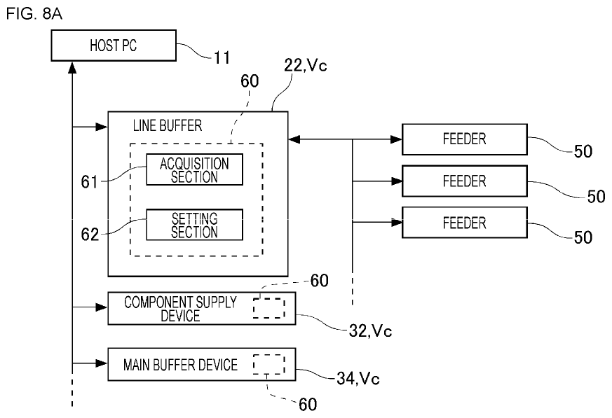

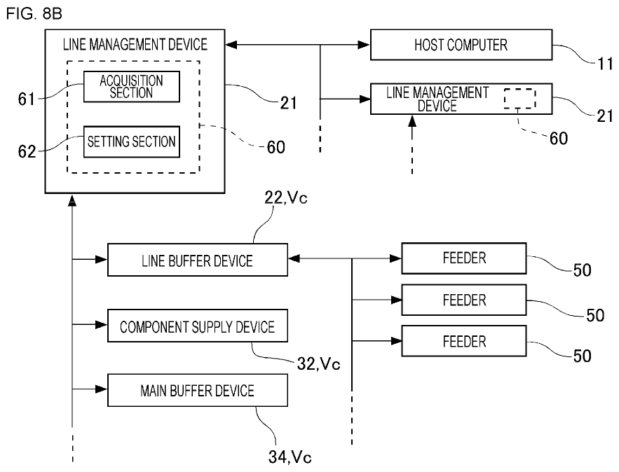

Specifically, operation management apparatus 60 may be configured to be provided in device Vc in which feeder 50 can be set. According to such a configuration, the type of device Vc can be easily acquired, and the setting of the operation mode for feeder 50 set in device Vc can be collectively managed. For example, as illustrated in FIG. 8A, operation management apparatus 60 is provided in each of line buffer device 22, component supply device 32, and main buffer device 34 as device Vc.

According to such an aspect, when feeder 50 is set in each device Vc individually or together with another feeder 50 via magazine 41, mode setting section 62 sets the operation mode according to the type of device Vc in which mode setting section 62 is provided. In this configuration as well, the same effects as in the embodiment are obtained.

For example, operation management apparatus 60 may be configured to be provided in host computer 11 or line management device 21 capable of communicating with device Vc. According to such a configuration, operation management apparatus 60 can be integrated without being distributed. Specifically, as illustrated in FIG. 8B, operation management apparatus 60 is provided in each line management device 21 for each production line Ln.

According to such an aspect, when feeder 50 is individually set in device Vc, line management device 21 acquires the type of device Vc and the identification code (ID) of the feeder. Then, acquisition section 61 acquires the type of device Vc, and mode setting section 62 sets the operation mode according to the type of device Vc. In this configuration as well, the same effects as in the embodiment are obtained.

In the embodiment, mode setting section 62 is configured to set the operation mode based on device information D1. On the other hand, mode setting section 62 may set the operation mode based on, for example, a request from device Vc together with the type of device Vc acquired by acquisition section 61.

For example, device Vc may use, as a request, an operation mode corresponding to a state (before use, after use, necessity of communication, or the like) of feeder 50 that is set, a switching timing between a normal mode and a power saving mode, or the like. Accordingly, mode setting section 62 may set the operation mode according to the type of device Vc in principle when there is no request, and may set the operation mode in consideration of the request when there is a request.

### REFERENCE SIGNS LIST

10: Production system, 11: Host computer, 12: Management warehouse, 13: Work area, Ln: Production line, 21: Line management device, 22: Line buffer device, 23: Loader, 30: Component mounter, 32: Component supply device, 34: Main buffer device, 41: Magazine, 45: Reel, 46: Carrier tape, 50: Feeder, 51: Feeder main body, 52: Tape guide, 53: Reel holding section, 54: Drive device, 542: Electric motor, 56: Feeder control device, 60: Operation management apparatus, 61: Acquisition section, 62: Mode setting section, 70: Work robot, 85: Worker, 91: Board, D1: Device information, Vc: Device

1. An operation management apparatus for a feeder, the apparatus comprising:
an acquisition section configured to acquire a type of a device in which a feeder configured to supply a component is set; and
a mode setting section configured to set an operation mode of the feeder including a normal mode in which a supply operation of the component is executable and a power saving mode in which power consumption is reduced as compared with the normal mode based on the acquired type of the device.

2. The operation management apparatus for a feeder according to claim 1, wherein
the type of the device includes a component supply device which is provided in a component mounter configured to mount the component supplied by the feeder on a board and in which multiple feeders are set, and
the mode setting section sets the operation mode of the feeder to the normal mode when the type of the device acquired by the acquisition section is the component supply device.

3. The operation management apparatus for a feeder according to claim 1, wherein
the type of the device includes a main buffer device which is provided in a component mounter configured to mount the component supplied by the feeder on a board and which is configured to accommodate a spare feeder, and a line buffer device which constitutes a production line of a product board together with the component mounter and which is configured to accommodate multiple feeders, and
the mode setting section sets the operation mode of the feeder to the power saving mode when the type of the device acquired by the acquisition section is the main buffer device or the line buffer device.

4. The operation management apparatus for a feeder according to claim 1, wherein the power saving mode is the operation mode in which power consumption is reduced by stopping at least some of functions of the feeder.

5. The operation management apparatus for a feeder according to claim 4, wherein
the feeder includes an electric motor constituting a drive device configured to feed and move a tape accommodating multiple components in the supply operation of the component, and
in the power saving mode, power supply to the electric motor is cut off to stop a function of the feeding and moving.

6. The operation management apparatus for a feeder according to claim 1, wherein the acquisition section and the mode setting section are provided in a feeder control device configured to control the supply operation of the component in the feeder.

7. The operation management apparatus for a feeder according to claim 6, wherein
the feeder control device stores in advance device information indicating a type of the device that is settable to the power saving mode, and
the mode setting section sets the operation mode of the feeder to the power saving mode when the type of the device acquired by the acquisition section is included in the device information.

8. The operation management apparatus for a feeder according to claim 1, wherein the acquisition section and the mode setting section are provided in an external device of the feeder.

9. The operation management apparatus for a feeder according to claim 1, wherein the power saving mode maintains power supply to a feeder control device configured to control the supply operation of the component in the feeder, and stops power supply to an electric drive device used in the supply operation of the component except for the feeder control device.

10. The operation management apparatus for a feeder according to any claim 1, wherein the power saving mode stops power supply to a feeder control device configured to control the supply operation of the component in the feeder, and stops power supply to an electric drive device used in the supply operation of the component except for the feeder control device.

11. An operation management method for a feeder, the method comprising:
an acquisition step of acquiring a type of a device in which a feeder configured to supply a component is set; and
a mode setting step of setting an operation mode of the feeder including a normal mode in which a supply operation of the component is executable and a power saving mode in which power consumption is reduced as compared with the normal mode based on the acquired type of the device.
